(19) United States
(12) Patent Application Publication
(10) Pub. No.: US 2010/0193825 A1
(43) Pub. Date: Aug. 5, 2010

(54) LIGHT-EMITTING DIODE PACKAGE AND METHOD FOR FABRICATING THE SAME

(76) Inventor: Chih-Wen Yang, Taipei (TW)

Correspondence Address: NORTH AMERICA INTELLECTUAL PROPERTY CORPORATION, P.O. BOX 506, MERRIFIELD, VA, 22116, US

(21) Appl. No.: 12/365,902

(22) Filed: Feb. 5, 2009

(51) Int. Cl. H01L 33/00; H01L 21/02

(52) U.S. Cl. 257/99; 438/26; 257/E33.056; 257/E21.002

(57) ABSTRACT

A light-emitting diode (LED) package is disclosed. The LED package includes a metal substrate, a first insulating polymer layer disposed on the metal substrate, an upper metal layer disposed on surface of the first insulating polymer layer, and at least a LED chip. The first insulating polymer layer includes a cavity and first insulating polymer layer surrounding the cavity includes a reflecting slope, and the LED chip is disposed in the cavity of the first insulating polymer layer and electrically connected to the upper metal layer.

### BACKGROUND OF THE INVENTION

1. Field of the Invention

The invention relates to a light-emitting diode package and method for making the same.

2. Description of the Prior Art

LED's are primarily of the surface mount type with leads that mount on the surface of a substrate, or of the type with leads that pass through the substrate for attachment. Surface mount LED leads are bent to form a plane parallel to the substrate surface. LED's of the later type are formed with leads which are perpendicular to the substrate surface.

Of the LED's which have leads that can be surface mounted, chip-type LED's have a favorable reputation. A typical chip-type LED is formed by die-bonding an LED chip to the surface at the bottom of a cavity in a transparent package with leads formed in the package. Wire-bonding is performed as required. Next, package encapsulating resin is introduced into the cavity to at least cover the LED chip. On the other hand, a single type of encapsulating resin may be used to enclose and fix in place an LED chip and leads without using a package.

Unfortunately, conventional design of either surface mount or chip-type LED packages typically has poor reflectivity and limits the overall luminance of the package. In addition, the current state-of-the-art of packaging technology for aforementioned LED's used in lighting module applications is not particularly well adapted for handling and assembly using high volume assembly methods. For example, surface mounting with reflow soldering of the LED's on the circuit boards using standard techniques is either currently not feasible and/or extremely expensive. It would therefore be desirable to provide a LED package well suited for use in the various industries that overcomes one or more of the foregoing disadvantages, drawbacks, or limitations.

### SUMMARY OF THE INVENTION

It is an objective of the present invention to provide a LED package with lower cost and improved reflectivity and overall luminance.

According to a preferred embodiment of the present invention, a light-emitting diode package is disclosed. The light-emitting diode package includes: a metal substrate; a first insulating polymer layer disposed on the metal substrate, wherein the first insulating polymer layer comprises a cavity and the first insulating polymer layer surrounding the cavity comprises a reflecting slope; an upper metal layer disposed on surface of the first insulating polymer layer; and at least a light-emitting diode chip disposed in the cavity of the first insulating polymer layer and electrically connected to the upper metal layer.

According to another aspect of the present invention, a method for fabricating a light-emitting diode package is disclosed. The method includes the steps of: providing a metal substrate; pre-molding an insulating polymer layer on the metal substrate, wherein the insulating polymer layer comprises a cavity; pre-molding an upper metal layer on the insulating polymer layer; placing at least a light-emitting diode chip in the cavity of the insulating polymer layer; and electrically connecting the light-emitting diode chip and the upper metal layer.

According to an embodiment of the present invention, a method for fabricating a light-emitting diode package is disclosed. The method includes the steps of: providing a metal substrate and an upper metal layer; fixing the metal substrate and the upper metal layer and injecting an insulating polymer material onto the metal substrate such that the insulating polymer material encloses a portion of the upper metal layer while forming a cavity on the metal substrate; placing at least a light-emitting diode chip in the cavity of the insulating polymer material; and electrically connecting the light-emitting diode chip and the upper metal layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-2 illustrate a method of using pre-molding process for fabricating a light-emitting diode package according to a preferred embodiment of the present invention.

FIG. 3 illustrates a structural view of the LED package shown in FIGS. 1-2.

FIG. 4 illustrates a perspective view of pre-molding an insulating polymer layer onto the upper metal layer according to an embodiment of the present invention.

FIG. 5 illustrates a structural view of the LED package shown in FIG. 4.

FIG. 6 illustrates a structural view of a LED package according to an embodiment of the present invention.

### DETAILED DESCRIPTION

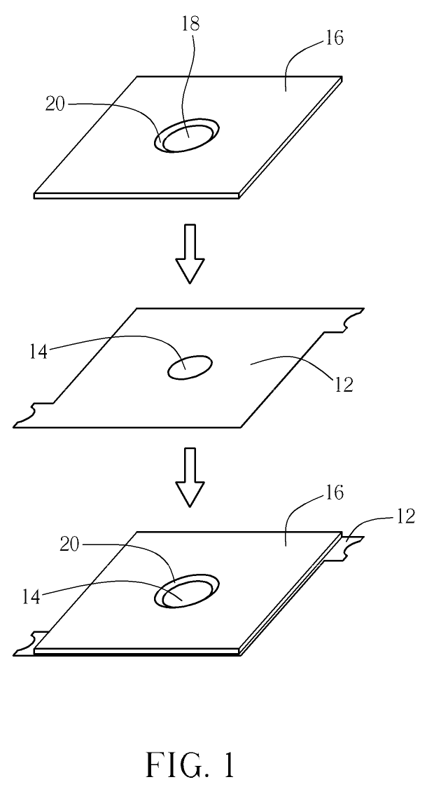

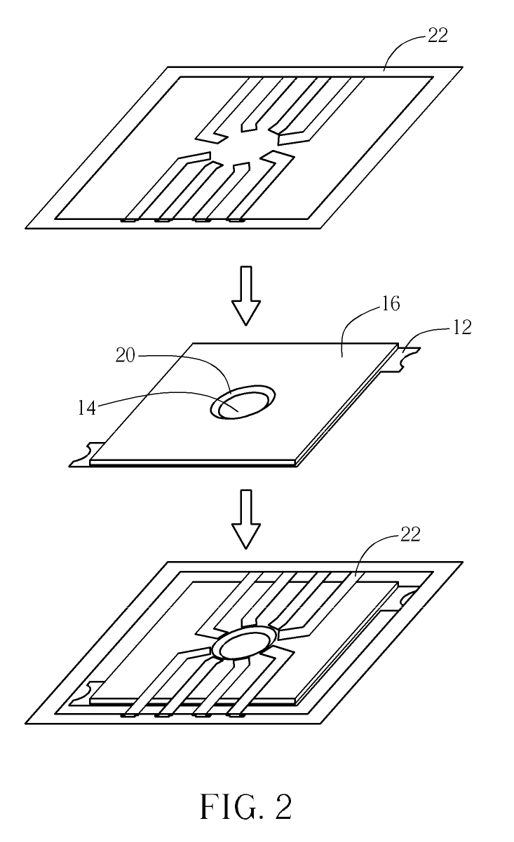

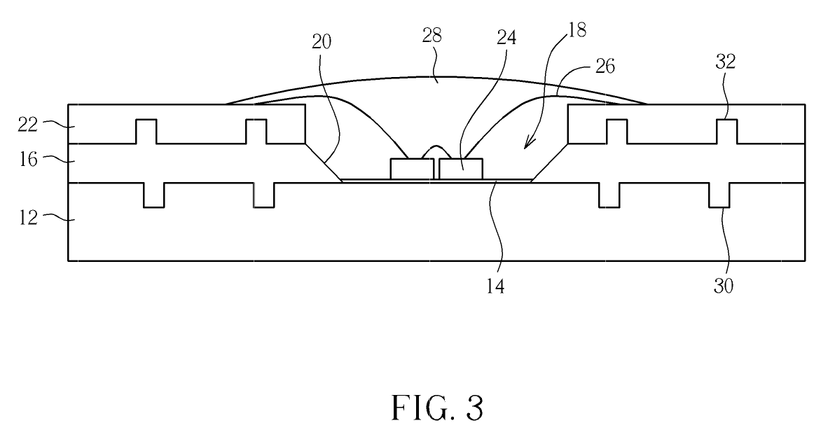

Referring to FIGS. 1-3, FIGS. 1-2 illustrate a method of using pre-molding process for fabricating a light-emitting diode package according to a preferred embodiment of the present invention, FIG. 3 illustrates a structural view of the LED package fabricated from FIGS. 1-2. As shown in FIGS. 1 and 3, a metal substrate 12 is provided. The metal substrate 12 is preferably a metal thin film, such as a lead frame, which is made of a material selected from Cu, Al, Ag, or alloy thereof. A plurality of vias 30 could be formed on the upper surface of the metal substrate 12, and the vias 30 may be formed by techniques such as drilling, injection, stamping, or compression.

A reflective layer 14 is coated on the upper surface of the metal substrate 12. Preferably, the reflective layer 14 is coated corresponding to the position of the LED chip disposed thereafter. In this embodiment, the reflective layer 14 is circular, and is coated relatively to the center of the metal substrate 12. However, the shape, quantity, area and location of the reflective layer 14 could be adjusted according to the quantity as well as the position of the LED chip, which are all within the scope of the present invention. The reflective layer 14 could be a metal layer selected from a group consisting of Al, Au, Ag, Ni, W, Ti and Pt.

Next, an insulating polymer layer 16 is pre-molded on the metal substrate 12. The insulating polymer layer 16 includes a cavity 18 formed relative to the center of the insulating polymer layer, in which the cavity 18 is formed to expose the reflective layer 14 as the insulating polymer layer 16 is pre-molded onto the metal substrate 12. Specifically, the insulating polymer layer 16 surrounding the cavity 18 has a slope 20, which is preferably fabricated for enhancing the reflectivity of light emitted by the LED chip. Despite only one cavity 18 is formed in the insulating polymer layer 16, an insulating polymer layer having a plurality of cavities could also be fabricated to suit the demand of the product.

The insulating polymer layer 16 is preferably composed of transparent insulating material such as liquid crystal polyester. During the pre-molding process, most of the insulating polymer layer 16 is adhered onto the upper surface of the metal substrate 12 while a portion of the insulating polymer layer 16 is molded into each via 30. The vias 30 enhance the adhesion between the insulating polymer layer 16 and the metal substrate 12 by grabbing onto the extended portion of the insulating polymer layer 16 while allowing the insulating polymer layer 16 to be tightly attached to the metal substrate 12.

After the insulating polymer layer 16 is pre-molded, another reflective layer (not shown) could be coated over the slope 20 of the cavity 18. This reflective layer could also be composed of similar material as the reflective 14 coated over the surface of the metal substrate 12, such as a metal layer selected from a group consisting of Al, Au, Ag, Ni, W, Ti and Pt, and this reflective layer preferably enhances the reflectivity of light illuminated by an LED chip disposed in the cavity 18.

As shown in FIG. 2, an upper metal layer 22 is pre-molded on the upper surface of the insulating polymer layer 16. Similar to the metal substrate 12, the upper metal layer 22 is also composed of a metal thin film such as lead frame, which could be made of a material selected from Cu, Al, Ag, or alloy thereof. The upper metal layer 22 may be extended to the exterior of the entire package and is preferably utilized as an electrode for connecting the LED chips disposed afterwards. A plurality of vias 32 is formed according to similar fashion on the bottom surface of the upper metal layer 22 by processes such as drilling, injection, stamping, or compression.

As the upper metal layer 22 is pre-molded onto the insulating polymer layer 16, the insulating polymer layer 16 is pressed against the bottom surface of the upper metal layer 22 such that a portion of the insulating polymer layer 16 is pressed into the vias 32 of the upper metal layer 22. This tightly adheres the insulating polymer layer 16 onto the upper metal layer 22.

After the metal substrate 12, the insulating polymer layer 16, and the upper metal layer 22 are pre-molded, a LED chip 24 is disposed in the cavity 18 of the insulating polymer layer 16 and a wire bonding process is performed by forming a plurality of wires 26 to electrically connect the LED chip 24 with the upper metal layer 22. According to an embodiment of the present invention, a semiconductor substrate (not shown) could be disposed between the LED chip 24 and the metal substrate 12 to reduce the expanding coefficient between the LED chip 24 and the metal substrate 12 while increasing the flexibility of the design and the life expectancy of the module. Despite only one LED chip 24 is shown in this embodiment, a plurality of LED chips could be disposed in the cavity 18 depending on the design of the product, which is also within the scope of the present invention. An encapsulation process is performed thereafter by filling the cavity 18 with an encapsulant 28 such as epoxy resin. The encapsulant 28 preferably encloses the LED chip 24, the wires 26, and a portion of the upper metal layer 22. This completes the fabrication of a LED package.

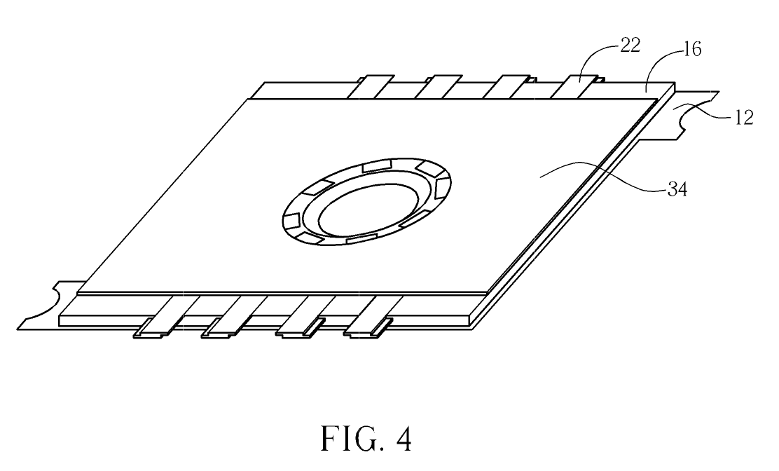

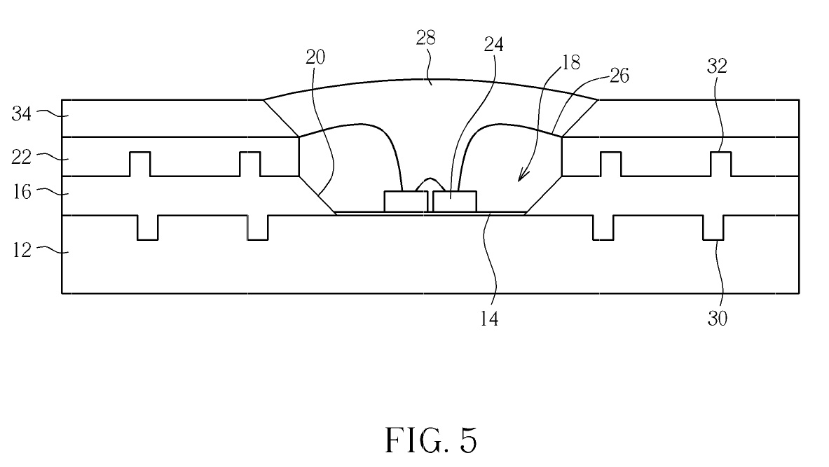

In addition to the exposed upper metal layer design, an additional reflective layer could be disposed on the upper metal layer 22 for increasing the reflectivity of the package. Referring to FIGS. 4 and 5, FIG. 4 illustrates a perspective view of pre-molding another insulating polymer layer onto the upper metal layer according to an embodiment of the present invention and FIG. 5 illustrates a structural view of the LED package shown in FIG. 4. As shown in FIGS. 4-5, after the metal substrate 12, the insulating polymer layer 16, and the upper metal layer 22 are pre-molded, another insulating polymer layer 34 could be coated directly on the upper surface of the upper metal layer 22 through pre-molding process. This insulating polymer layer 34 preferably provides protection for the wires 26 while enhancing the reflectivity of the package. The insulating polymer layer 34 is preferably composed of liquid crystal polyester. After the insulating polymer layer 34 is formed, die bonding and wire bonding processes could be performed to adhere at least one LED chip 24 onto the reflective layer 14 disposed on the metal substrate 12 and electrically connect the LED chip 24 and the upper metal layer 22 with a plurality of wires 26, and an encapsulant 28 is formed thereafter to enclose the LED chip 24, the wires 26, and a portion of the insulating polymer layer 34.

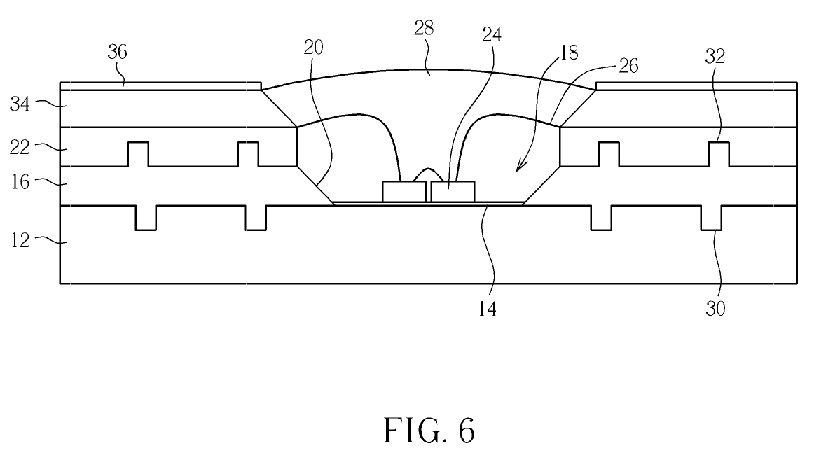

According to an embodiment of the present invention, a reflective layer 36 composed of metal could be coated on the insulating polymer layer 34 to form another LED package design, as shown in FIG. 6. The reflective layer 36 could be composed of material similar to the aforementioned metals used for fabricating the reflective layer 34, such as a material selected from a group consisting of Al, Au, Ag, Ni, W, Ti and Pt. In this design, the upper metal layer 22 would eventually be sandwiched between the two insulating polymer layers 16 and 34.

In addition to the aforementioned embodiment of using a pre-molding process for fabricating a LED package, an injection process could also be employed for fabricating the same LED package. Referring back to FIG. 5, which further illustrates a method for fabricating a LED package according to an embodiment of the present invention.

As shown in FIG. 5, a metal substrate 12 and an upper metal layer 22 is provided. Each of the metal substrate 12 and the upper metal layer 22 is composed of a lead frame, such as a thin metal film made of material selected from Cu, Al, Ag, or alloy thereof. A plurality of vias 30 and 32 is then formed on both upper surface of the metal substrate 12 and bottom surface of the upper metal layer 22, in which the vias 30 and 32 may be formed by techniques such as drilling, injection, stamping, or compression.

Next, a reflective layer 14 is coated on the upper surface of the metal substrate 12. Similar to the aforementioned embodiment, the reflective layer 14 is coated corresponding to a circle and substantially to the center of the metal substrate 12, and the shape, quantity, area and location of the reflective layer 14 could be adjusted according to the quantity and position of the LED chip, and the reflective layer 14 could be composed of metal selected from a group consisting of Al, Au, Ag, Ni, W, Ti and Pt.

The metal substrate 12 and the upper metal layer 22 are then fixed in placed, and an insulating polymer material 16 is injected onto the metal substrate 12. The injection process preferably fills the vias 30 and 32 and covers major area of the metal substrate 12 with insulating polymer material and encloses the entire the upper metal layer 22 except the end portion. The injection is controlled that a cavity 18 is formed relative to the center of the insulating polymer material 16. The cavity 18 exposes the reflective layer 14 coated on the metal substrate 12 and the insulating polymer material 16 surrounding the cavity 18 forms a slope 20 for enhancing the reflectance of light emitted by the LED chip 24.

After the insulating polymer material solidifies, the upper metal layer 22 is sandwiched between two insulating polymer layers 16 and 34, as shown in FIG. 5. A reflective layer (not shown) could be selectively coated over the slope 20 of the cavity 18 and a reflective layer 36 could be selectively coated on upper surface of the insulating polymer layer 34, as suggested in the aforementioned embodiments. The material of these reflective layers could be chosen from the same material as the reflective layer 14 coated on the metal substrate 12, such as material selected from a group consisting of Al, Au, Ag, Ni, W, Ti and Pt.

After the reflective layer 36 is coated, a LED chip 24 is disposed in the cavity 18 of the insulating polymer layer 16 and a wire bonding process is performed by forming a plurality of wires 26 to electrically connect the LED chip 24 with the upper metal layer 22. An encapsulation process is then performed by filling an encapsulant 28 into the cavity 18 while enclosing the LED chip 24, the wires 26, and a portion of the upper metal layer 22.

Overall, the present invention proposes a novel design of LED package by forming an insulating polymer layer composed preferably of liquid crystal polyester layer between a metal substrate and an upper metal layer through a pre-molding process or an injection process. Each of the metal substrate and the upper metal layer is preferably composed of a lead frame, and the liquid crystal polyester layer is utilized for enhancing the luminance of the package while offering a choice of much lower cost. In addition, a plurality of reflective layers is selectively coated over various spots of the package for improving the reflectivity of the package. For instance, a reflective layer is coated on the upper surface of the metal substrate with respect to the location of the LED chip, a reflective layer is coated on the slope of the insulating polymer layer, and a reflective layer is coated on the upper surface of the upper metal layer. Through the utilization of liquid crystal polyester and numerous reflective layers, it would be desirable to provide a LED package well suited for use in various industries while overcoming conventional limitations such as high fabrication cost and poor luminance.

Those skilled in the art will readily observe that numerous modifications and alterations of the device and method may be made while retaining the teachings of the invention.

What is claimed is:

1. A light-emitting diode package, comprising:
a metal substrate;
a first insulating polymer layer disposed on the metal substrate, wherein the first insulating polymer layer comprises a cavity and the first insulating polymer layer surrounding the cavity comprises a reflecting slope;
an upper metal layer disposed on surface of the first insulating polymer layer; and
at least a light-emitting diode chip disposed in the cavity of the first insulating polymer layer and electrically connected to the upper metal layer.

2. The light-emitting diode package of claim 1, wherein the first insulating polymer layer comprises liquid crystal polyester.

3. The light-emitting diode package of claim 1, wherein each of the metal substrate and the upper metal layer comprise a lead frame.

4. The light-emitting diode package of claim 1, wherein the metal substrate and the upper metal layer comprise a plurality of vias therein.

5. The light-emitting diode package of claim 1, further comprising a reflective layer coated over the surface of the upper metal layer, wherein the reflective layer comprises metal or insulating polymer.

6. The light-emitting diode package of claim 1, further comprising a second insulating polymer layer disposed on the upper metal layer.

7. The light-emitting diode package of claim 6, wherein the second insulating polymer layer comprises liquid crystal polyester.

8. The light-emitting diode package of claim 1, further comprising a reflective layer coated over the surface of the metal substrate.

9. The light-emitting diode package of claim 1, further comprising a semiconductor substrate disposed between the light-emitting diode chip and the metal substrate.

10. The light-emitting diode package of claim 6, further comprising a reflective layer coated over the surface of the second insulating polymer layer.

11. A method for fabricating a light-emitting diode package, comprising:
providing a metal substrate;
pre-molding a first insulating polymer layer on the metal substrate, wherein the first insulating polymer layer comprises a cavity;
pre-molding an upper metal layer on the first insulating polymer layer;
placing at least a light-emitting diode chip in the cavity of the first insulating polymer layer; and
electrically connecting the light-emitting diode chip and the upper metal layer.

12. The method of claim 11, wherein the first insulating polymer layer comprises liquid crystal polyester.

13. The method of claim 11, wherein each of the metal substrate and the upper metal layer comprise a lead frame.

14. The method of claim 11, further comprising coating a second insulating polymer layer over the upper surface of the upper metal layer.

15. A method for fabricating a light-emitting diode package, comprising:
providing a metal substrate and an upper metal layer;
fixing the metal substrate and the upper metal layer and injecting an insulating polymer material onto the metal substrate such that the insulating polymer material encloses a portion of the upper metal layer while forming a cavity on the metal substrate;
placing at least a light-emitting diode chip in the cavity of the insulating polymer material; and
electrically connecting the light-emitting diode chip and the upper metal layer.

16. The method of claim 15, wherein the insulating polymer material comprises liquid crystal polyester.

17. The method of claim 15, wherein each of the metal substrate and the upper metal layer form a lead frame.

18. The method of claim 15, further comprising forming a plurality of vias in the metal substrate and the upper metal layer.
